(19) United States
(12) Patent Application Publication
(10) Pub. No.: US 2025/0372340 A1
(43) Pub. Date: Dec. 4, 2025

(54) MAGNETIC SHIELDING OF THE PHOTOMULTIPLIER IN THE MAGNETIC IMMERSION FIELD

(71) Applicant: FEI Company, Hillsboro, OR (US)

(72) Inventors: Petr Glajc, Brno (CZ); Jana Dubnická Midlíková, Brno (CZ); Radovan Vašina, Brno (CZ)

(73) Assignee: FEI Company, Hillsboro, OR (US)

(21) Appl. No.: 18/677,563

(22) Filed: May 29, 2024

(51) Int. Cl. H01J 37/244; H01J 37/14; H01J 37/26

(52) U.S. Cl. CPC H01J 37/244; H01J 37/14; H01J 37/261; H01J 2237/0264; H01J 2237/1035; H01J 2237/2443; H01J 2237/2445

(57) ABSTRACT

Charged-particle detectors using scintillators are situated in a vacuum chamber and include a photomultiplier tube (PMT) that is situated at or near a pole piece of a magnetic objective lens. To maintain satisfactory PMT operation, the PMT is situated within a PMT shield constructed of a high saturation value magnetic material. With the disclosed shields, PMT operation in strong magnetic fields is satisfactory, even for magnetic field magnitudes of at least 0.5 T.

### FIELD

The disclosure pertains to charged-particle detectors.

### BACKGROUND

Magnetic immersion lenses are commonly used in charged-particle microscopes such as SEMs and TEMs to produce high resolution images. In such microscopes, a magnetic immersion lens generally extends a magnetic field along an incoming electron beam to a sample to improve controllability of beam spot size at the sample. Images are generally formed by detection of secondary electrons (SEs) or backscattered electrons (BSEs) from a sample in the presence of the magnetic immersion lens. The high magnetic fields produce by magnetic immersion lenses alters the functioning of detector electronics in the chamber. To obtain high SE or BSE collection efficiency, a detector should be placed close to the sample to gather the largest number of SEs/BSEs. However, for systems that include magnetic immersion lenses, regions close to samples are associated with high magnetic field strengths. Conventional SE/BSE detectors use scintillators that produce scintillation light in response to BSEs/SEs and a light guide situated to direct the scintillation light to a photomultiplier tube situated well away from the sample such as outside of a vacuum chamber. Such conventional approaches tend to be inefficient and improved approaches are needed.

### SUMMARY

The disclosure pertains to charged-particle detectors that use photomultiplier tubes (PMTs) to detect scintillation light emitted in response to reception of charged particles by a scintillator material. PMTs are provided with magnetic shields that permit PMTs to be situated proximate pole pieces of magnetic lenses at locations that are subject to high magnetic fields. The PMT shields can be formed of high saturation value magnetic materials so that the PMT shield is effective in high field regions. Scintillation light is directed to shielded PMTs through one or more apertures defined in the pole piece to provide a light optical path from a charged-particle optical axis of the pole piece to a PMT. Placing such a charged-particle detector proximate a magnetic lens can permit higher detection sensitivities even when subjected to magnetic field magnitudes greater than 0.5 T without significant changes in the magnetic fields used by a magnetic lens such as a magnetic immersion lens. Thus, improved detection efficiencies can be achieved without unacceptable changes in charged-particle imaging or processing.

The foregoing and other features and advantages of the disclosure will become more apparent from the following detailed description, which proceeds with reference to the accompanying figures.

### BRIEF DESCRIPTION OF THE DRAWINGS

FIG. 1 illustrates a representative charged-particle beam (CPB) optical system that includes a charged-particle (CP) detector situated near a pole piece of a magnetic objective lens, the CP detector using a photomultiplier (PMT) situated in a PMT magnetic shield formed of a high saturation magnetic material.

FIG. 2A illustrates a representative pole piece of a magnetic objective lens and a CP detector situated proximate the pole piece.

FIG. 2B further illustrates the pole piece of FIG. 2A.

FIG. 2C further illustrates the CP detector of FIG. 2A.

FIG. 3 illustrates a CP detector in which a scintillator serves as a light guide.

FIG. 4 illustrates a representative example of a PMT shield situated about a portion of a PMT that contains a PMT focusing electrode and a dynode chain.

FIG. 5 illustrates a representative PMT shield having a portion that defines an aperture situated to admit scintillation light to a faceplate of a PMT.

FIG. 6 is a schematic illustrating a CP detector that includes a casing that is secured to or situated to contact a pole piece.

FIGS. 7A-7B are perspective view of a pole piece and a casing of a CP detector.

FIG. 8A illustrates a configuration of a pole piece and a PMT shield drawn to scale for providing substantial reduction of magnetic field in a cavity configured to receive a PMT.

FIG. 8B illustrates PMT signal magnitude as a function of shielding for various magnetic field magnitudes and selected materials.

FIG. 9 illustrates a representative method of attenuating magnetic fields associated with a magnetic objective lens using a PMT shield formed of a high saturation magnetic material.

FIG. 10 illustrates a representative PMT shield that encloses a PMT.

FIG. 11 illustrates a representative PMT shield that encloses a PMT and is spaced apart from a PMT envelope.

FIG. 12 illustrates a representative PMT shield that extends to a PMT base.

FIG. 13 illustrates a representative PMT shield that extends beyond a PMT base.

FIG. 14 illustrates a representative PMT shield that includes slots.

FIG. 15 illustrates a PMT shield adapted for use with a side-on PMT.

FIG. 16 illustrates a representative pole piece of a magnetic objective lens and a CP detector having a side-on PMT situated proximate the pole piece.

### DETAILED DESCRIPTION

### Introduction and Definitions

The disclosure pertains generally to charged-particle beam (CPB) optical systems and instruments such as electron microscopes.

As used herein, “image” refers to a viewable image presented for visual inspected to a viewer such as with a display device or a stored representation that can be used to produce such a viewable image such as, for example, a TIFF, JPG, bitmap, or other data file on a memory device.

Scintillation refers to optical radiation produced in response to reception of a charged-particle beam by a scintillator material (hereinafter “scintillator”). Typical materials for a scintillator include organic and inorganic crystals, plastic scintillators such as polyethylene naphphthalate or other doped or undoped polymers, glasses, or others. For the applications described herein, high scintillation efficiency is preferred along with vacuum compatibility.

Lightguide refers to a transparent or translucent member operable to direct optical radiation between an input and an output and can be formed of plastics, glasses, fused silica or other materials both crystalline and non-crystalline. Plastics can be convenient as they can be conveniently shaped as needed. Scintillators can be configured to serve as lightguides in addition to providing scintillation.

As used herein, propagating charged particles are referred to as charged-particle beams (CPBs) and need not be collimated. In typical applications, electron or ion beams are directed to a sample of interest and reflected or scattered portions of these beams and/or secondary emission responsive to the incident beam or beams are detected.

In some examples, particular locations of electronics associated with photomultiplier tube (PMT) operation such as bias resistors, amplifiers, and power supplies are shown but these electronics can be situated at any convenient locations within or without a PMT shield or can be arranged so that portions are situated at different locations.

PMT shields are referred to as effectively reducing magnetic field magnitude (or effectively shielding) at PMT locations when magnetic fields that would otherwise be present of magnitudes of 0.1 T, 0.2 T, 0.5 T, 1.0 T or more are reduced in magnitude by a factor of at least 10, 20, 50, or 100. PMT shields can also be referred to as effectively shielding when configured so that PMT gain is at least 80% or 90% of the gain produced in the absence of magnetic field at locations at which magnetic fields in operation of a magnetic lens would otherwise reduce PMT gain by 20%, 50%, 75%, or more.

PMT shields are generally discussed in the examples as being cylinders, portions of cylinders or other shapes having cylindrically symmetric cross-sections. Such symmetric shapes can be convenient for practical implementations but PMT shields can have arbitrary shapes with rectangular, hexagonal, oval, elliptical, or other regular or irregular cross-sections. It can be practical to have a PMT shield that defines a cavity that provides little or no gap between a PMT and the PMT shield, but PMT shields having larger cavities can be used as well.

Focusing magnetic fields at regions between a distal end of a pole piece and a sample are referred to as substantially unperturbed by a PMT shield when each of the focusing vector components of the magnetic field in these regions are changed by less than 1%, 0.5%, or 0.1% by the PMT shield.

The expression “optical axis” is used to refer to an axis associated either with light propagation or CPB propagation.

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

For the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatuses are referred to as “lowest”, “best”, “minimum,” or the like. It will be appreciated that such descriptions are intended to indicate that a selection among many useful functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

### EXAMPLE 1

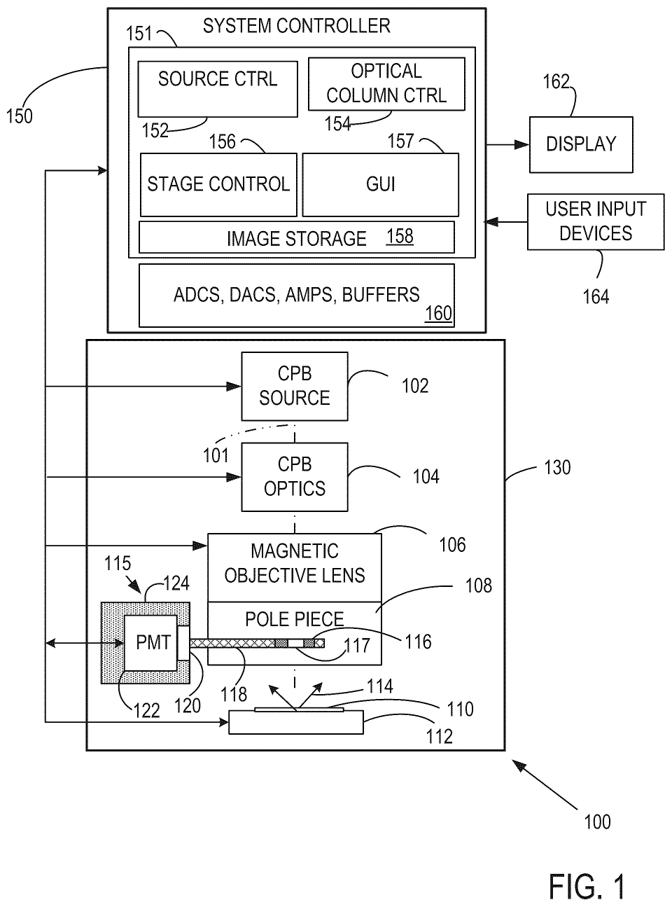

Referring to FIG. 1, a charged-particle beam (CPB) microscope (typically an electron microscope) 100 includes a CPB source 102 situated to direct a CPB along an optical axis 101 to CPB optics 104 such as one or more condenser lenses, stigmators, beam deflectors, apertures, or other CPB optics that can shape, focus, deflect or otherwise process the CPB. A magnetic objective lens 106 that includes a pole piece 108 is situated downstream of the CPB optics 104 and focusses the CPB for delivery to a sample 110. The sample 110 is secured to a substrate stage 112 for positioning a region of interest of the sample 110 with respect to the CPB from the magnetic objective lens 106. In response to an incident CPB from the magnetic objective lens 106, a return CPB 114 is directed back towards the magnetic objective lens 106. The return CPB 114 can include one or more or all of scattered or reflected portions of the incident CPB and secondary emission in response to the incident CPB.

A charged-particle (CP) detector 115 is situated to receive portions of the returned CPB 114 and produce an electrical signal in response. In this example, the CP detector 115 includes a scintillator 116 that is optically coupled to a lightguide 118 to deliver scintillation light (hereinafter “scintillation”) to photomultiplier tube (PMT) 122 through an aperture 120 defined in a PMT shield 124. The lightguide 118 extends towards the optical axis 101 into a cavity defined by the pole piece 108. The scintillator 116 can be situated on the optical axis 101 and provided with an aperture 117 to permit transmission of the CPB to the sample 110. A circular disc with a central circular aperture or a tapered, conical aperture is a convenient shape for the scintillator 116 and can promote efficient detection of the returned CPB 114 but other shapes can be used and the scintillator 116 can be situated to one side of the optical axis 101 instead of on the optical axis 101.

In this example, the CPB source 102, the CPB optics 104, the magnetic objective lens 106 (and the pole piece 108), the CPB detector 115, and the sample 110 are situated in a vacuum chamber 130 that is evacuated in use by one or more vacuum pumps and other vacuum components that are not shown in FIG. 1.

A system controller 150 includes a processor or other logic hardware such as a gate array, an application specific integrated circuit (ASIC), a complex programmable logic device (CPLD), programmable array logic (PAL) (all referred to generally herein as “processors” or “controllers”). The system controller 150 includes one or more memory devices 151 that store processor-executable instructions for CPB source control 152, CPB optics and magnetic objective lens control 154 (referred to generally as “the optical column”), stage control 156, a graphical user interface (GUI) 157 for operator use, and image storage 158. The system controller 150 also includes electronics 160 such as analog-to-digital convertors (ADCs), digital to analog convertors (DACs), amplifiers, buffers, voltage sources for supplying suitable electrical voltages and/or currents and to process signals produced by the CP detector 115. Typically one or more user input devices 164 such as keyboards or pointing devices are provided for user input and control along with a display 162 that can be used for operator input and to display acquired images.

### EXAMPLE 2

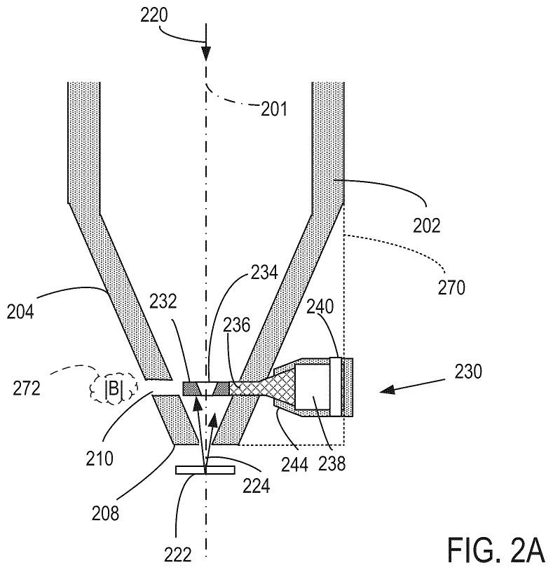

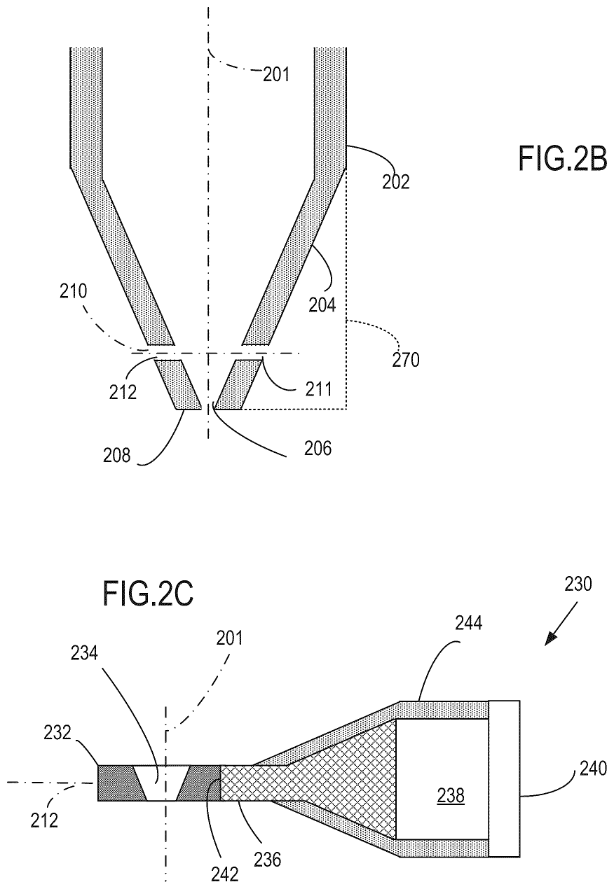

With reference to FIGS. 2A-2C, a magnetic objective lens includes a pole piece 202 having a conical surface 204 that defines a CPB aperture 206 on a CPB optical axis 201 at a distal surface 208. The pole piece 202 has a conical taper as indicated by the conical surface 204 that tapers to narrow at the distal surface 208. Pole pieces taper as illustrated but other shapes can be used. The pole piece 202 also defines a passage that extends along a detection axis 212 and terminates at apertures 210, 211 on the conical surface 204. In some examples, the passage extends to define only a single aperture on the conical surface 204, but opposing apertures as shown are generally preferred to maintain symmetry. The magnetic lens and the pole piece 202 are situated on the CPB optical axis 201 to direct a CPB 220 to a sample 222. In response to the CPB 220, charged particles 224 such as scattered portions of the CPB 220 or secondary electrons are directed through the CPB aperture 206 and received by a CPB detector 230.

The CPB detector 230 includes a scintillator 232 that produces scintillation that is optically coupled to a photomultiplier (PMT) 238 with a lightguide 236. The scintillator 232 is provided with a scintillator aperture 234 that permits transmission of the CPB 220 to the sample 222. As shown, the scintillator aperture 234 tapers from a larger diameter to smaller diameter along the CPB optical axis 201. PMT electronics 240 are connected to the PMT 238 to provide suitable PMT bias and to receive PMT signals associated with CPs received by the scintillator 232. In this example, the lightguide 236 and the scintillator 232 are edge coupled or face coupled as shown at 242. The PMT 238 is situated in a PMT shield 244 that is selected to reduce magnetic field strength associated with the pole piece 202 and operation of the magnetic lens, typically by factors of at least 2, 5, 10, 20, 50, 10, 20, 50 or more, even in magnetic immersion fields of magnitude of 0.1, 0.2, 0.5, 1.0, 2 T or more. To provide suitable shielding in such fields, the PMT shield 244 is formed of one or more high saturation value magnetic materials such as permendur, supermendur, permalloy, pure iron (99% or more purity), carbon steel with less than 0.5. 0.2, 0.1% carbon, nickel-iron alloys, cobalt-iron alloys, cobalt-iron-vanadium alloys, mu-metal, or other materials, and in many examples, preferably materials having saturation fields of at least 0.1, 0.2, 0.5, 1.0, or 2.0 T. Some materials, such as mu-metal, have saturation fields that are too low to be successfully used in high magnetic field regions.

The CPB detector 230 can be situated proximate the pole piece 202. For example, some or all of the PMT 238 can be situated in a volume 270 defined by the conical surface 204 of the pole piece 202 and a portion of a plane containing the distal surface 208 of the pole piece 202. In the volume 270, magnetic field strengths tend to be large enough to substantially interfere with PMT operation in the absence of the PMT shield 244. In addition, the magnetic field strengths in the volume 270 are sufficiently high that conventional shielding materials such as mu-metal cannot provide adequate shielding.

### EXAMPLE 3

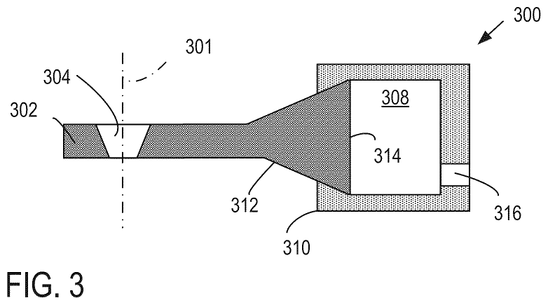

In a representative example shown in FIG. 3, a CP detector 300 includes a scintillator 302 that defines an aperture 304 for transmission of a CPB along an optical axis 301. In this example, the scintillator 302 also serves as a light guide to couple scintillation to a cavity 308 defined in a PMT shield 310 that is configured to retain a PMT. The scintillator 302 has a tapered portion 312 that permits insertion into a detection aperture of a pole piece further than possible without tapering but tapering is not required. The scintillator 302 also includes an output surface 314 for optical coupling to a PMT. The PMT shield 310 further defines a passage 316 for electrical connection to a PMT situated in the cavity 308. In practical examples, the PMT shield is made of a high saturation field magnetic material as discussed above.

### EXAMPLE 4

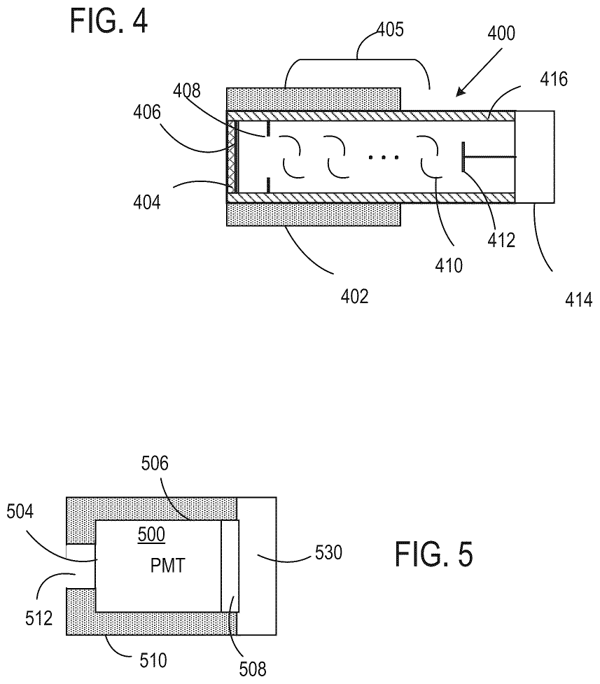

Referring to FIG. 4, a PMT 400 (in this example, a so-called “head-on” PMT) is situated in a cavity defined by a PMT shield 402. The PMT 400 includes a faceplate 404 and a photoemissive surface 406. Electrons emitted from the photoemissive surface 406 are directed by an electrode 408 to a dynode chain 405 that includes one or more dynodes such as representative dynodes 410 that provide charge multiplication such that an increased charge is received at a PMT anode 412. The dynodes of the dynode chain 405, the electrode 408, and the PMT anode 412 are electrically coupled to a PMT base 414 that provides electrical connections for dynode chain bias and detected signals. The PMT 400 has a PMT envelope 416 that terminates at the faceplate 404 and at the PMT base 414. The PMT envelope surrounds the dynode chain, the anode 412, and the electrode 408. As shown in FIG. 4, the PMT shield 402 extends along the PMT envelope 416 to contain at least a portion (and typically all) of the dynode chain 405 to provide adequate shielding for operation of the PMT 400.

### EXAMPLE 5

Referring to FIG. 5, a PMT 500 is situated in a cavity defined by a PMT shield 510. The PMT 500 includes a faceplate 504, a base 508, and an envelope 506 that extends from the base 508 to the faceplate 504. A portion of the PMT shield 510 situated at the faceplate 504 defines an aperture 512 that permits scintillation to be incident to the faceplate 504. Another portion of the PMT shield 510 is situated along the envelope 506. The PMT base 508 provides electrical connections for dynode chain bias and coupling of detected signals to PMT electronics 530.

### EXAMPLE 6

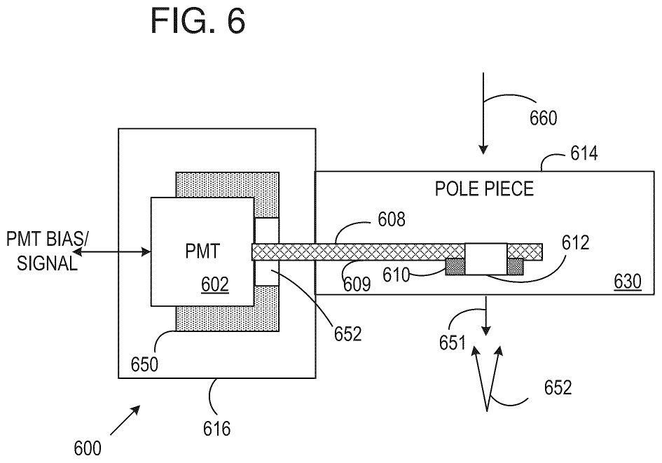

Referring to FIG. 6, a CP detector 600 includes a PMT 602 that is coupled to a lightguide 608 that extends through an aperture 652 defined in a PMT shield 650 into a volume defined by a pole piece 630 of a magnetic lens. The lightguide 608 is optically coupled to a scintillator 610 situated on a surface 609 of the lightguide 608 that faces a sample. In this example, the scintillator 610 and the lightguide 608 define an aperture 612 for transmission of an incident CPB 660 to a sample. For clarity, a CPB 651 is shown exiting the aperture 612 for incidence to a sample and a returned beam 652 is shown as directed to the scintillator 610.

In the example of FIG. 6, the PMT 602 and the PMT shield 650 (or portions thereof) are secured to a casing 616 that is fixed with respect to the pole piece 630. In some examples, the casing 616 is made of a non-magnetic material and is secured to the pole piece 630. As shown in additional examples below, one or more components of the CPB detector 600 such as the PMT shield 650 and the casing 616 can be shaped to correspond to portions of a pole piece surface to permit the CPB detector 600 to be situated proximate a pole piece.

### EXAMPLE 7

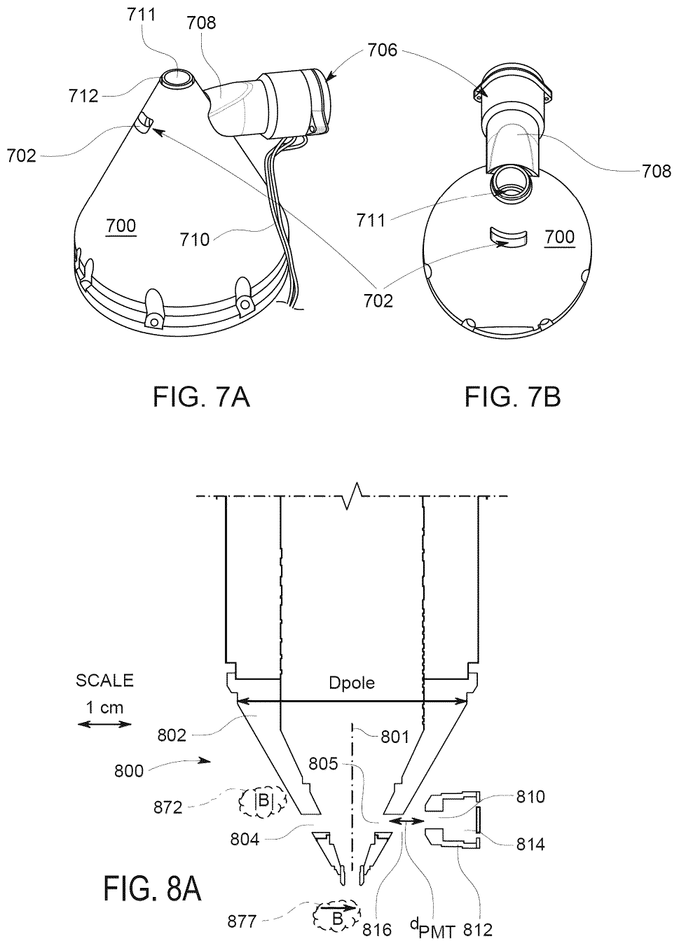

Referring to FIGS. 7A-7B, a CP detector casing 706 made of a non-magnetic material or non-ferromagnetic material contacts and is secured to a pole piece 700 defining an aperture 711 at a distal surface 712 to be situated facing a sample to be imaged. The CP detector casing 706 includes a tapered section 708 that fits into an aperture situated opposite to and typically similar or identical to an aperture 702 in the pole piece 700. The tapered section 708 permits the CP detector casing 706 to be situated closer to an optical axis defined by the pole piece 700 that would be possible with a cylindrical shape of the same diameter or other untapered shape. Electrical connections to a PMT situated in the CP detector casing 706 can be provided with one or more electrical cables such as cable 710.

### EXAMPLE 8

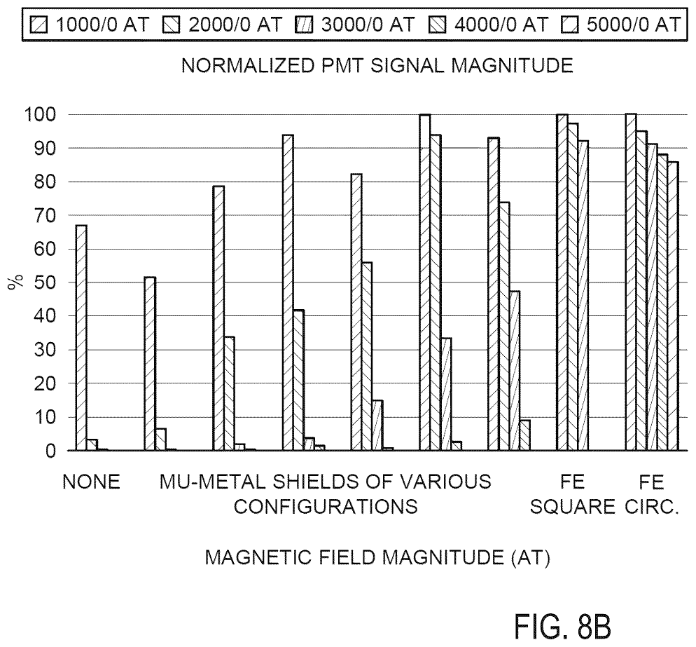

FIG. 8A illustrates a representative scaled arrangement of a magnetic lens pole piece 802 having a largest diameter of Dₚₒₗₑ and a PMT shield 812 situated a distance 816 (d_{PMT}) from the pole piece 802 and defining a CPB optical axis 801. The pole piece 802 defines apertures 804, 805 that permit scintillation produced within the pole piece 802 to be directed to a PMT situated in a cavity 814 in the PMT shield 812 through the aperture 810. The PMT shield 812 can be situated proximate the pole piece 802 and as used herein, a PMT shield is “proximate” a pole piece if an aperture in the shield for receiving scintillation is spaced a distance less than 0.5Dₚₒₗₑ, 0.4Dₚₒₗₑ, 0.3Dₚₒₗₑ, 0.2Dₚₒₗₑ, 0.1Dₚₒₗₑ, or 0.05Dₚₒₗₑ from the pole piece 802 along an axis perpendicular to a CPB optical axis.

In use, the pole piece 802 is associated with magnetic fields used for CPB imaging that can be large enough to impair operation of PMTs situated in such fields. As shown in FIG. 8A, a magnetic field magnitude within the PMT shield is reduced by a magnitude of at least a factor of 2, 5, 10, 20, 50, or 100 from the magnetic field magnitude that would be at the same location absent the PMT shield. For example, a magnetic field magnitude at a location 872 (corresponding to a magnetic field magnetic magnitude at a PMT location absent the PMT shield) can be in a range 0.1 T to 0.5 T while a magnetic field magnitude within then cavity 814 is in ranges such as 0.01 T to 0. 05 T, or 0.01 T to 0.005 T. In one example, a magnetic field magnitude of 0.3 T is reduced in the cavity to 0.004 T. In addition, while the PMT shield 812 substantially shields the cavity 814, focusing magnetic field components at a location 877 are altered by less than 1%, 0.5%, or 0.2% because of the presence of the PMT shield 812. Thus, the PMT shield 812 although made of a magnetic material can be situated close to a pole piece without unacceptable compromises to CPB imaging.

FIG. 8B illustrates the improvement in PMT signal magnitude with and without PMT shields of mu-metal and pure iron. At a relative magnetic field magnitude of 2000 ampere-turns (AT), normalized PMT signal is less than 5% without a PMT shield. With mu-metal shields of various kinds, normalized PMT signal magnitude is improved while for iron PMT shield of square or circular cross-section, normalized PMT signal magnitude is greater than 80-85% for all magnetic field strengths shown.

### EXAMPLE 9

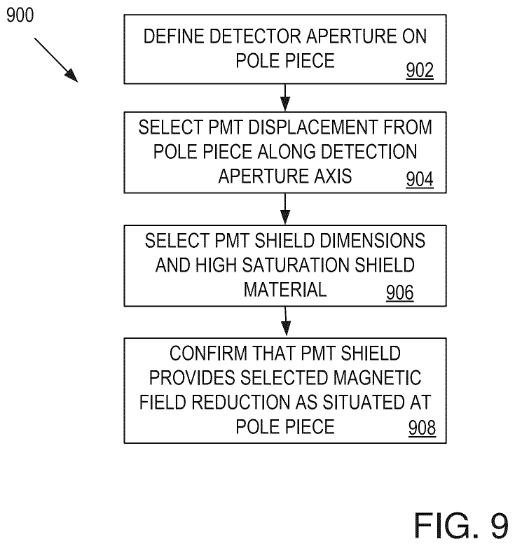

Referring to FIG. 9, a representative method 900 includes defining a detector aperture on a pole piece 902 and selecting a PMT displacement from the pole piece at 904. At 906, PMT shield dimensions and materials are selected, and at 908, the selected shield dimensions, materials, and placement are evaluated to determine if the PMT shield provides sufficient shielding to provides suitable PMT gain as compared with an unshielded PMT.

### EXAMPLE 10

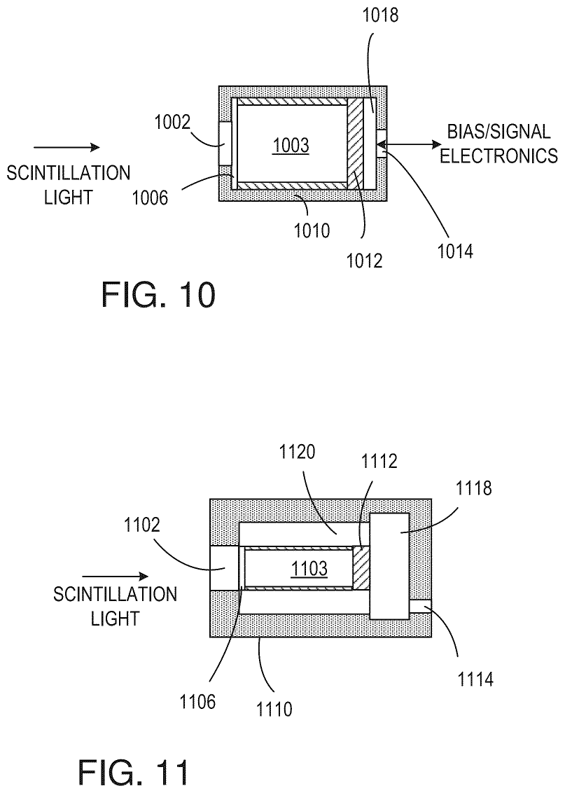

In a representative example shown in FIG. 10, a PMT shield 1010 for a CP detector defines a cavity situated to retain a PMT 1003 and an aperture 1002 for transmission of scintillation to a PMT faceplate 1006. The PMT 1003 includes PMT base 1012 that is situated within the PMT shield 1010 and electrical connections are provided using an aperture 1014 in the PMT shield 1010. The PMT shield 1010 can also define a volume 1018 for PMT electronics, if desired, or the volume 1018 can be omitted. In this example, the PMT shield 1010 encloses the PMT 1003 except to admit scintillation via the aperture 1002 and to provide electrical connections via the aperture 1014.

### EXAMPLE 11

In a representative example shown in FIG. 11, a PMT shield 1110 for a CP detector defines a cavity configured to retain a PMT 1103 so that the PMT 1103 is spaced away from the PMT shield 1110 by a cavity 1120 and the PMT shield 1110 defines an aperture 1102 for transmission of scintillation to a PMT faceplate 1106. The PMT 1003 includes a PMT base 1112 that is situated within the PMT shield 1110 and electrical connections are provided via an aperture 1114 in the PMT shield 1110. The PMT shield 1110 can also define a volume 1118 for PMT electronics, if desired, or the volume 1118 can be omitted. In this example, the PMT shield 1110 encloses the PMT 1103 except to admit scintillation via the aperture 1102 and to provide electrical connections via the aperture 1114.

### EXAMPLE 12

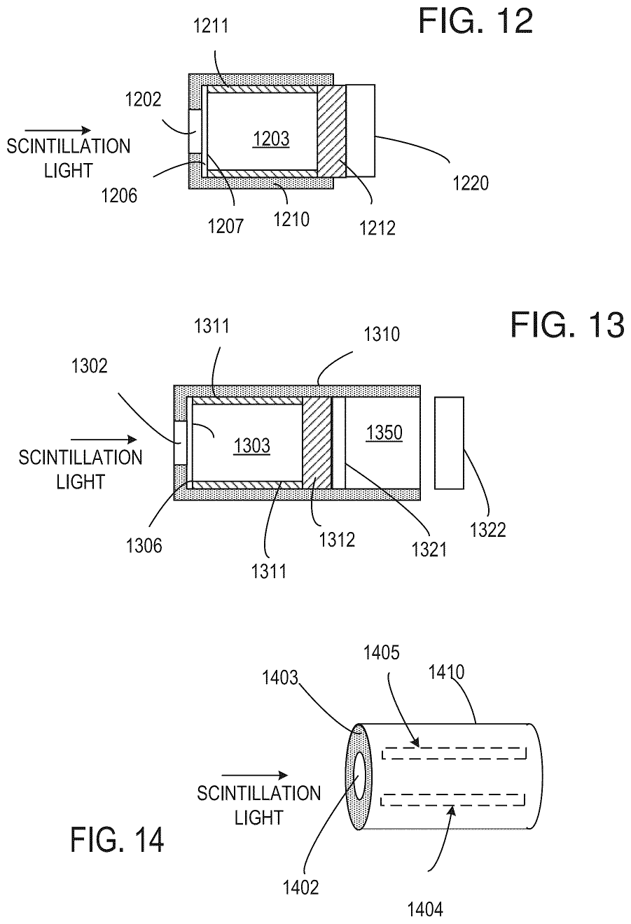

In a representative example shown in FIG. 12, a PMT shield 1210 for a CP detector defines a cavity configured to retain a PMT 1203 and an aperture 1202 for transmission of scintillation to a PMT faceplate 1206 and a photocathode 1207. The PMT 1203 includes PMT base 1212 that extends beyond the PMT shield 1210 while a PMT envelope 1211 is contained with the PMT shield 1210. Electronics 1220 can be secured to the PMT base 1212 or situated remotely.

### EXAMPLE 13

In a representative example shown in FIG. 13, a PMT shield 1310 for a CP detector defines a cavity configured to retain a PMT 1303 and an aperture 1302 for transmission of scintillation to a PMT faceplate 1306 and an associated photocathode. The PMT 1303 including a PMT base 1312 is situated within the PMT shield 1310 and the PMT shield 1301 extends a distance 0.1, 0.25, 0.5, 0.75, 1.0, 1.5, 2.0, or more times a PMT diameter beyond the PMT base 1312 to define a cavity 1350. Electronics can be secured to the PMT base 1312 at 1321 or remotely as shown at 1322.

### EXAMPLE 14

In the examples, PMT shields are shown generally as sections of cylindrical shells. However, PMT shields are not limited to circular cross-sections but can have any cross-section as convenient to provide sufficient magnetic field reduction for PMT operation. Representative examples include oval, elliptical, polygonal, or other regular or irregular cross-sections. In addition, PMT shields can be provided with slots or apertures or can have varying thickness, again subject to the need to provide sufficient magnetic field reduction for PMT operation. As shown in FIG. 14, a cylindrical PMT shield 1410 has a wall 1403 with a constant thickness but that is provided with slots 1404, 1405 that can extend into a cavity 1402 that retains a PMT or only partially into the wall 1403. Slots are shown in FIG. 14, but other aperture shapes or other arrangements that reduce PMT wall thickness in at least some locations can be used, whether or not they extend into the cavity 1402.

### EXAMPLE 15

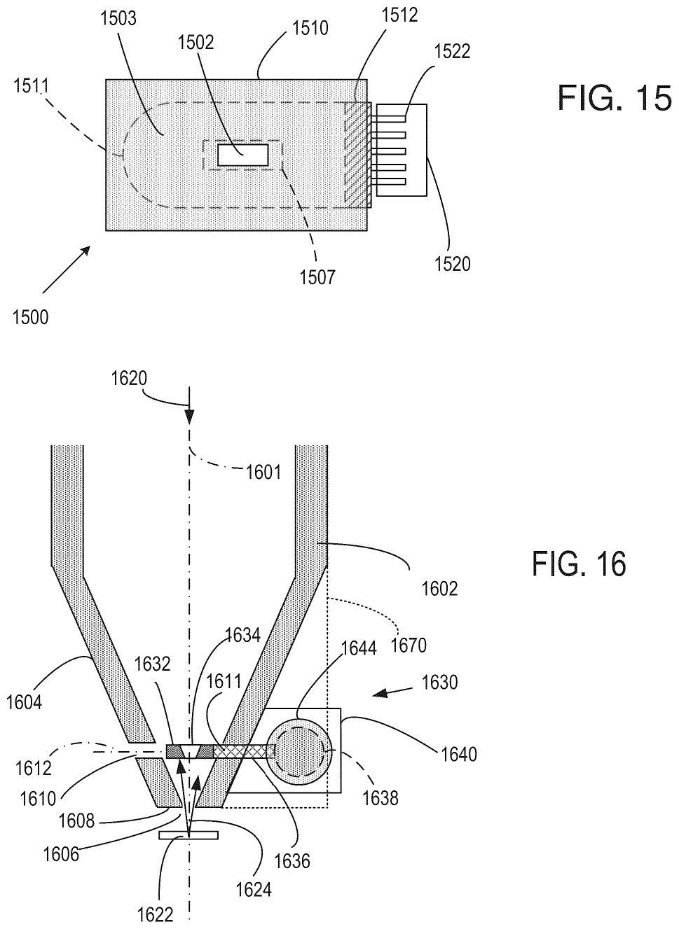

FIG. 15 illustrates a portion of a representative CP detector 1500 that includes a side-on PMT 1503 that is situated at least partially within a PMT shield 1510 that defines an aperture 1502 for transmission of scintillation to a PMT photocathode 1507. The PMT 1503 includes PMT base 1512 that may extend beyond the PMT shield 1510 while a PMT envelope 1511 is contained with the PMT shield 1510. Electronics 1520 can be secured to the PMT base 1512 by a set of PMT connection pins 1522 or situated remotely. The PMT shield 1510 is made of a suitable magnetic material to substantially reduce or eliminate magnetic fields produced by magnetic lenses so that PMT operation is substantially unchanged by the presence of magnetic fields produced by magnetic immersion lenses.

### EXAMPLE 16

FIG. 16 illustrates a CP detector 1630 such as illustrated in FIG. 15 situated to detect charged particles in response to irradiation using a magnetic immersion lens. With reference to FIG. 16, a magnetic objective lens includes a pole piece 1602 having a conical surface 1604 that defines a CPB aperture 1606 on a CPB optical axis 1601 at a distal surface 1608. The pole piece 1602 also defines a passage that extends along a detection axis 1612 and terminates at apertures 1610, 1611 on the conical surface 1604. The passage can extend to define only a single aperture on the conical surface 1604, but opposing apertures as shown are generally preferred to maintain symmetry. The pole piece 1602 is situated on the CPB optical axis 1601 to direct a CPB 1620 to a sample 1622. In response to the CPB 1620, charged particles 1624 such as scattered portions of the CPB 1620 or secondary electrons are directed through the CPB aperture 1606 and received by the CPB detector 1630.

The CPB detector 1630 includes a scintillator 1632 that produces scintillation that is optically coupled to a side-on photomultiplier (PMT) 1638 with a lightguide 1636. The scintillator 1632 is provided with a scintillator aperture 1634 that permits transmission of the CPB 1620 to the sample 1622. As shown, the scintillator aperture 1634 tapers from a larger diameter to smaller diameter along the CPB optical axis 1601. PMT electronics connected to the PMT 1638 to provide suitable PMT bias and to receive PMT signals associated with CPs received by the scintillator 1632 are not shown. The PMT 1638 is situated in a PMT shield 1644 that is selected to reduce magnetic field strength associated with the pole piece 1602 and operation of the magnetic lens, typically by factors of at least 2, 5, 10, 20, 50, or more, even in magnetic immersion fields of magnitude of 0.1, 0.2, 0.5, 1.0, 2 T or more. To provide suitable shielding in such fields, the PMT shield 1604 is formed of one or more high saturation value magnetic materials such as permendur, supermendur, permalloy, pure iron (99% or more purity), carbon steel with less than 0.5. 0.2, 0.1% carbon, nickel-iron alloys, cobalt-iron alloys, cobalt-iron-vanadium alloys, mu-metal, or other materials, and in many examples, preferably materials having saturation fields of at least 0.1, 0.2, 0.5, 1.0, or 2.0 T.

The CPB detector 1630 can be situated proximate the pole piece 1602. For example, some or all of the PMT 1638 can be situated in a volume 1670 defined by the conical surface 1604 of the pole piece 1602 and a portion of a plane containing the distal surface 1608 of the pole piece 1602. In the volume 1670, magnetic field strengths tend to be large enough to substantially interfere with PMT operation in the absence of the PMT shield 1644. In addition, the magnetic field strengths in the volume 1670 are sufficiently high that conventional shielding materials such as mu-metal cannot provide adequate shielding. In the example of FIG. 16, the PMT 1638 and the PMT shield 1644 are situated within a non-magnetic casing 1640 that is secured to the pole piece 1602.

### Additional Examples

Example 1 is a charged-particle beam (CPB) microscope, including: a CPB optical system operable to direct a CPB along a CPB optical system axis towards a sample; a magnetic lens operable to produce a magnetic immersion field and shape the CPB at the sample, the magnetic lens situated on the CPB optical system axis and including a pole piece that defines a bore through which the CPB is directed to the sample, the pole piece having a conical taper so that a diameter of the pole piece decreases along the CPB optical system axis towards the sample; and a CPB detector adapted to be situated in vacuum chamber containing the CPB optical system and that includes: a scintillator situated in the bore of the pole piece and operable to receive charged particles from the sample in response to irradiation of the sample with the CPB and produce scintillation light that is directed along a passage defined in the pole piece, a photomultiplier tube (PMT) situated to receive the scintillation light from the passage in the pole piece at a PMT photocathode, the PMT having a PMT base and a PMT envelope that extends from the PMT base, and a PMT magnetic shield that defines a cavity that receives the PMT and a first aperture situated so that the PMT photocathode receives the scintillation light through the first aperture in the PMT magnetic shield.

Example 2 includes the subject matter of any Example 1, and further specifies that at least a portion of the PMT shield is situated proximate the pole piece in a volume bounded by a conical surface of the pole piece.

Example 3 includes the subject matter of any preceding example, wherein the first PMT magnetic shield is formed of one or more of a nickel-iron alloy, a cobalt-iron alloy, pure iron, or low carbon steel.

Example 4 includes the subject matter of any preceding example, and further specifies that the PMT magnetic shield formed of a magnetic material having a saturation field of at least Example 0.5 T.

Example 5 includes the subject matter of any preceding example, and further specifies that the passage defined in the pole piece extends to apertures that are oppositely situated on a conical surface of the pole piece.

Example 6 includes the subject matter of any preceding example, and further specifies that the CPB detector includes a lightguide optically coupled to the scintillator and the PMT to direct the scintillation light to the PMT, wherein the lightguide extends at least in part along the passage defined in the pole piece towards the PMT.

Example 7 includes the subject matter of any preceding example, and further specifies that the cavity defined by the PMT magnetic shield has a circular or rectangular cross-section.

Example 8 includes the subject matter of any preceding example, and further specifies that the PMT is a head-on PMT and the PMT magnetic shield extends from a PMT faceplate to a distal end of a PMT base.

Example 9 includes the subject matter of any preceding example, and further specifies that the PMT magnetic shield includes a portion situated along a PMT envelope and a portion situated at the PMT faceplate, the portion situated at the PMT faceplate defining the first aperture that receives the scintillation light and transmits the scintillation light to the PMT photocathode.

Example 10 includes the subject matter of any preceding example, and further specifies that the PMT magnetic shield is fixed with respect to the pole piece.

Example 11 includes the subject matter of any preceding example, and further includes a housing made from a non-ferromagnetic material situated about at least a portion of the PMT magnetic shield, wherein the housing is fixed to the pole piece.

Example 12 includes the subject matter of any preceding example, and further specifies that the PMT is a side-on PMT and the PMT magnetic shield is situated to extend to surround a PMT envelope and at least a portion of a PMT base.

Example 13 includes the subject matter of any preceding example, and further specifies that the PMT magnetic shield is operable to reduce a magnetic field of at least Example 0.1 T at a PMT location by a factor of at least Example 20.

Example 14 includes the subject matter of any preceding example, and further specifies that the scintillator defined a CPB transmissive aperture on the CPB axis and is optically edge or face coupled to the lightguide to direct the scintillation to the PMT photocathode.

Example 15 includes the subject matter of any preceding example, and further specifies that the cavity defined by the PMT magnetic shield includes a portion that extends beyond the PMT as situated in the cavity at at least one end by a distance that is greater than or equal to a PMT diameter.

Example 16 includes the subject matter any preceding example, and further specifies that the PMT magnetic shield surrounds the PMT as situated in the cavity and defines a second aperture through which the PMT is electrically coupled.

Example 17 is a method, including: situating a photomultiplier (PMT) proximate a pole piece of a magnetic lens to receive scintillation light responsive to a charged-particle beam (CPB) incident to a sample; and providing a PMT magnetic shield about at least a portion of the PMT to reduce a magnetic field associated with the magnetic lens at the PMT by at least a factor of 20 for magnetic field strengths of at least Example 0.1 T.

Example 18 includes the subject matter of Example 17, and further specifies that the scintillation light is directed through a passage defined in the pole piece to the PMT, the passage terminating at an aperture in a conical surface of the pole piece.

Example 19 includes the subject matter of any of Examples 17-18, and further includes: situating a scintillator within a bore of the pole piece to produce the scintillation light; and coupling the scintillation light through the passage with a lightguide that is optically coupled to the scintillator.

Example 20 includes the subject matter of any of Examples 17-19, and further specifies that the passage extends through the pole piece to form opposing apertures about a CPB optical axis.

Example 21 is a charged-particle beam (CPB) detector situatable in a vacuum chamber of a charged-particle microscope and in a magnetic immersion field of a magnetic objective lens, the charged-particle beam detector comprising: a photomultiplier tube (PMT); a PMT magnetic shield defining a cavity configured to contain at a PMT envelope and a least a portion of a PMT base, the PMT shield formed of a high saturation magnetic material; and a scintillator operable to produce scintillation light in response to charged particles associated with a CPB of the charged- particle microscope.

Example 22 includes the subject matter of example 21 and further specifies that the PMT magnetic shield is operable to reduce a magnetic field produced by the magnetic objective lens by at least a factor of 20 in the cavity defined by the PMT shield for magnetic immersion field strengths of at least 0.1 T.

In view of the many possible embodiments to which the principles of the disclosed technology may be applied, it should be recognized that the illustrated embodiments are only preferred examples of the and should not be taken as limiting the scope of the disclosure.

We claim:

1. A charged-particle beam (CPB) microscope, comprising:
a CPB optical system operable to direct a CPB along a CPB optical system axis towards a sample;
a magnetic lens operable to produce a magnetic immersion field and shape the CPB at the sample, the magnetic lens situated on the CPB optical system axis and including a pole piece that defines a bore through which the CPB is directed to the sample; and
a CPB detector adapted to be situated in vacuum chamber containing the CPB optical system and that includes:
a scintillator situated in the bore of the pole piece and operable to receive charged particles from the sample in response to irradiation of the sample with the CPB and produce scintillation light that is directed along a passage defined in the pole piece,
a photomultiplier tube (PMT) situated to receive the scintillation light from the passage in the pole piece at a PMT photocathode, and
a PMT magnetic shield that defines a cavity that receives the PMT and a first aperture situated so that the PMT photocathode receives the scintillation light through the first aperture in the PMT magnetic shield.

2. The CPB microscope of claim 1, wherein the pole piece has a conical taper so that a diameter of the pole piece decreases along the CPB optical system axis towards the sample and at least a portion of the PMT magnetic shield is situated proximate the pole piece in a volume bounded by a conical surface of the pole piece.

3. The CPB microscope of claim 1, wherein the PMT magnetic shield is formed of one or more of a nickel-iron alloy, a cobalt-iron alloy, pure iron, or low carbon steel.

4. The CPB microscope of claim 1, wherein the PMT magnetic shield is formed of a magnetic material having a saturation field of at least 0.5 T.

5. The CPB microscope of claim 1, wherein the passage defined in the pole piece extends to apertures that are oppositely situated on a conical surface of the pole piece.

6. The CPB microscope of claim 1, wherein the CPB detector includes a lightguide optically coupled to the scintillator and the PMT to direct the scintillation light to the PMT, wherein the lightguide extends at least in part along the passage defined in the pole piece towards the PMT.

7. The CPB microscope of claim 1, wherein the cavity defined by the PMT magnetic shield has a circular or rectangular cross-section.

8. The CPB microscope of claim 1, wherein the PMT is a head-on PMT and the PMT magnetic shield extends from a PMT faceplate to a distal end of a PMT base.

9. The CPB microscope of claim 8, wherein the PMT magnetic shield includes a portion situated along a PMT envelope and a portion situated at the PMT faceplate, the portion situated at the PMT faceplate defining the first aperture that receives the scintillation light and transmits the scintillation light to the PMT photocathode.

10. The CPB microscope of claim 1, wherein the PMT magnetic shield is fixed with respect to the pole piece.

11. The CPB microscope of claim 1, further comprising a casing made from a non-ferromagnetic material situated about at least a portion of the PMT magnetic shield, wherein the casing is fixed to the pole piece.

12. The CPB microscope of claim 1, wherein the PMT is a side-on PMT and the PMT magnetic shield is situated to extend to surround a PMT envelope and at least a portion of a PMT base.

13. The CPB microscope of claim 1, wherein the PMT magnetic shield is operable to reduce a magnetic field of at least 0.1 T at a PMT location by a factor of at least 20.

14. The CPB microscope of claim 6, wherein the scintillator defines a CPB transmissive aperture on the CPB axis and is optically edge or face coupled to the lightguide to direct the scintillation light to the PMT photocathode.

15. The CPB microscope of claim 1, wherein the cavity defined by the PMT magnetic shield includes a portion that extends beyond the PMT as situated in the cavity at least at one end by a distance that is greater than or equal to a PMT diameter.

16. The CPB microscope of claim 1, wherein the PMT magnetic shield surrounds the PMT as situated in the cavity and defines a second aperture through which the PMT is electrically coupled.

17. A method, comprising:
situating a photomultiplier (PMT) proximate a pole piece of a magnetic lens to receive scintillation light responsive to a charged-particle beam (CPB) incident to a sample; and
providing a PMT magnetic shield about at least a portion of the PMT to reduce a magnetic field associated with the magnetic lens at the PMT by at least a factor of 20 for magnetic field strengths of at least 0.1 T.

18. The method of claim 17, wherein the scintillation light is directed through a passage defined in the pole piece to the PMT, the passage terminating at an aperture in a conical surface of the pole piece.

19. The method of claim 18, further comprising:
situating a scintillator within a bore of the pole piece to produce the scintillation light; and
coupling the scintillation light through the passage with a lightguide that is optically coupled to the scintillator.

20. The method of claim 19, wherein the passage extends through the pole piece to form opposing apertures about a CPB optical axis.

21. A charged-particle beam (CPB) detector situatable in a vacuum chamber of a charged-particle microscope and in a magnetic immersion field of a magnetic objective lens, the CPB detector comprising:
a photomultiplier tube (PMT);
a PMT magnetic shield defining a cavity configured to contain at a PMT envelope and a least a portion of a PMT base, the PMT shield formed of a high saturation magnetic material; and
a scintillator operable to produce scintillation light in response to charged particles associated with a CPB of the charged-particle microscope.

22. The CPB detector of claim 21, wherein the PMT magnetic shield is operable to reduce a magnetic field produced by the magnetic objective lens by at least a factor of 20 in the cavity defined by the PMT shield for magnetic immersion field strengths of at least 0.1 T.
